(19) United States
(12) Patent Application Publication
(10) Pub. No.: US 2023/0333337 A1
(43) Pub. Date: Oct. 19, 2023

(54) Component Carrier and Method of Manufacturing the Same

(71) Applicant: AT&S Austria Technologie & Systemtechnik Aktiengesellschaft, Leoben (AT)

(72) Inventor: Günther Mayr, Kraubath (AT)

(21) Appl. No.: 18/338,287

(22) Filed: Jun. 20, 2023

Related U.S. Application Data
(63) Continuation-in-part of application No. 16/535,419, filed on Aug. 8, 2019.

(51) Int. Cl. G02B 6/42

(52) U.S. Cl. CPC G02B 6/4277

(57) ABSTRACT

A component carrier includes a laminated stack having electrically insulating layer structures and electrically conductive layer structures; and an electrically insulating cap structure selectively covering an optical waveguide at an exterior surface of the laminated stack. A method for manufacturing a component carrier is also disclosed.

### CROSS-REFERENCE TO RELATED APPLICATIONS

The present application is a continuation-in-part of U.S. Pat. Application No. 16/535,419, filed Aug. 8, 2019, the contents of which are incorporated herein by reference in its entirety.

### TECHNICAL FIELD

Embodiments disclosed herein relate to a component carrier and methods for manufacturing a component carrier, respectively.

### BACKGROUND ART

A conventional component carrier comprises a laminated stack having a plurality of electrically conductive layer structures and a plurality of electrically insulating layer structures. Conductive traces are arranged on the stack. Especially in RF modules and other high frequency product applications such as 5G applications as well as in Solid State Drives (SSD), where for example critical signals are routed via the traces on the outermost layer over a bend region, the signal integrity is an issue. Usually, shields made of prefabricated metal sheets are surface-mounted by a mounting or assembling machine in a separate manufacturing step to cover and shield the traces. However, such shields can be mounted only to specific areas of the component carrier. Furthermore, the size of the component carrier is increased by such shields.

### SUMMARY

There may be a need to provide a component carrier having improved signal integrity and a smaller size, and to provide a simplified method of manufacturing the component carrier in an efficient and reliable manner. These needs are addressed by the subject matter of the respective independent claims.

According to an exemplary embodiment of the disclosure, a component carrier includes a laminated stack having a plurality of electrically conductive layer structures and a plurality of electrically insulating layer structures; and a cap structure selectively covering an optical waveguide at an exterior surface of the laminated stack.

According to another exemplary embodiment of the disclosure, there is provided a method of manufacturing a component carrier, the method includes the steps of providing a laminated stack having a plurality of electrically conductive layer structures and a plurality of electrically insulating layer structures; and forming a cap structure selectively covering an optical waveguide at an exterior surface of the laminated stack.

According to the present disclosure, a separate step of assembling or mounting a shielding or shield, which is conventionally made of a metal sheet, can be omitted so that the manufacturing method is simplified and costs are reduced. The cap structure according to the present disclosure can be arranged at any location of the component carrier and not only at specific areas of a conventional component carrier. In particular, the cap structure may protrude from an exterior surface of the laminated stack of the component carrier. In an example, the cap structure is located on the laminated stack. In another example, the cap structure is partially embedded in the stack and further protrudes from an exterior surface of the laminated stack of the component. Furthermore, the component carrier can be provided in any size and in a compact size, in particular if the cap structure is manufactured by plating, sputtering, a (photo)lithography process and/or three-dimensional printing. The cap structure may comprise inorganic material, for example a metal, in particular copper or aluminum, or glass. Additionally and or alternatively, the cap structure may comprise organic material, in particular organic polymer material, for example epoxy resin. Furthermore, the cap structure may comprise or consist of material layers arranged one layer on top of another layer. In one example, a layer comprising organic material and a further layer comprising the same or a different organic material may be located next to the other respective layer, while having direct contact. In another example, a layer comprising inorganic material and a further layer comprising organic material may be located next to the other respective layer, while having direct contact.

### OVERVIEW OF EMBODIMENTS

In the context of the present disclosure, the term “optical waveguide” may particularly denote a structure that guides optical waves, such as electromagnetic waves in the visible, infrared and/or ultraviolet wavelength ranges. In the context of the present application, optical waveguides can be dielectric waveguides. They can be made up of concentric layers; in the center can be an optical core, which is surrounded by a cladding with a somewhat lower refractive index and by further protective layers made of an electrically insulating or conductive material. The optical core can have a diameter of a few micrometers to over one millimeter. Propagation of electromagnetic radiation in a waveguide may be performed with low loss of electromagnetic radiation energy by spatially restricting the transmission of the electromagnetic radiation energy, in particular to one direction. In particular, an optical waveguide may be connected to a fiber connector by a horizontal connection extending parallel to a main surface direction and/or by a vertical connection perpendicular to a main surface direction. In an example, the optical waveguide may comprise or consist of one sustained layer. Alternatively, the optical waveguide may comprise a plurality of layers.

In the context of the present disclosure, the term “selectively covering” may particularly denote a spatial association between two product features, in particular the optical waveguide and the cap structure. Thereby the cap structure may be located such that the optical waveguide is at least partially in contact with the cap structure. In a preferred example, at least one side of the length of the optical waveguide may be in direct contact with at least one side of the cap structure. Thereby the cap structure may be configured as a protection or shielding structure of the optical waveguide.

In embodiments, even critical signals, which are routed on inner or outer layers, can be cladded at the top and/or bottom sides of the optical waveguide. The cap structure can be configured to protect a signal integrity of any signal being transported within the optical waveguide, which particularly includes electric and optical signals. For example, the component carrier according to the present disclosure can shield traces between antenna arrays from external sources and can ensure increased performance due to reduced impact of noise or disturbances, in particular for 5G or other RF applications with antenna arrays on an external layer. The cap structure can furthermore have benefits for a mechanical protection of the optical waveguide. The cap structure can either be an electrically conducting or an insulating cap structure.

In the following, further exemplary embodiments of the present disclosure will be explained.

In an embodiment, the optical waveguide is a waveguide core cladded by the cap structure which is an electrically insulating cap structure. This may bring the additional advantage of mechanically protecting the optical waveguide. In the context of the present application, the term “waveguide core” may particularly denote a central layer structure of the optical waveguide configured for transmitting a light (for instance a light signal). The optical waveguide core may be at least partially embedded in the cap structure. In a preferred example, the waveguide core is in direct contact with the cap structure. Alternatively, additional material, for example electrically insulating material or electrically conductive material may be located between the waveguide core and the cap structure.

In an embodiment, the cap structure and at least one of the electrically insulating layer structures are made of the same material. This may bring the advantage of using material which is established and highly reliable in PCB industry. In a preferred example, the cap structure and at least one of the electrically insulating layer structures may be in direct contact and thereby envelope the waveguide core at its total circumference. In other words, a coaxial feature may be created having a waveguide core as an inner member and the outer shell member of the coaxial feature may comprise the cap structure and at least one of the electrically insulating layer structures. In another example, the cap structure and at least one of the electrically insulating layer structures may be in direct contact to create a portion, where the waveguide core is exposed. In other words, a further coaxial feature may be created, however, in this example, the coaxial feature may have a cavity and the outer shell member of the coaxial feature to create a radial entrance or exit to the waveguide core.

In an embodiment, the cap structure, the optical waveguide, and/or at least one of the electrically insulating layer structures is made of an optical polymeric material and/or glass material. This may bring the advantage of reducing signal loss when light (or a light signal) is transmitted through an optical wave guide.

In an embodiment, the stack is a printed circuit board, wherein the optical waveguide is fully embedded in the cap structure. This may bring the advantage of producing the stack with high product quality or small extension(s), due to the PCB manufacturing processes. Furthermore, the optical waveguide comprising the waveguide core may be encompassed by a further protection layer.

In an embodiment, the cap structure comprises a layer thickness being at least 3 times larger than a layer thickness of the optical waveguide. This relationship allows less signal losses so that a high-quality signal transmission can be ensured.

In an embodiment, the optical waveguide comprises a cross-section having an edged shape or a round shape. This may bring the advantage of higher freedom of the component carrier design. In example, the edged shape may comprise triangular, rectangular, or hexagonal shapes. In a different example, the round shape may comprise circular or elliptical shape.

In an embodiment, the cap structure and/or at least one of the electrically insulating layer structures comprises a filling material, the filling material preferably has a distance of at least 20 µm from the optical waveguide. This may bring the advantage of changing at least one physical property of the cap structure and/or the at least one of the electrically insulating layer structures, for example the Young’s modulus, while still ensuring reliable transmission of the electromagnetic waves. Thus, this may enhance the product quality of the component carrier and may reduce the number of scrap parts. In an example, the filling material may comprise inorganic material, for example magnesium hydroxide, calcium hydroxide, or silicon oxide, in particular silicon dioxide. In another example, the filling material may comprise organic material, for example organic polymer material, in particular epoxy resin or polyethylene terephthalate.

In an embodiment, the cap structure and/or at least one of the electrically insulating layer structures comprises a porous material having open and/or closed pores being filled by a fluid, preferably gas filled pores. This may bring the advantage of reducing the weight of the component carrier, while still ensuring reliable transmission of the electromagnetic waves. In an example, the porous material may comprise air, nitrogen, carbon dioxide, or argon. In another example, the porous material may comprise ethylene glycol, glycerin, or water.

In an embodiment, a plurality of the optical waveguides, preferably up to 64 optical waveguides, are arranged side by side without direct contact with each other. This may bring the advantage of increasing the transmission of electromagnetic waves in the component carrier. In an example, the plurality of optical waveguides may be arranged randomly without direct contact to at least one respective other optical waveguide. In a preferred other example, the plurality of optical waveguides may be arranged in a structured matrix, for example a 1 × 8 matrix, a 3 × 4 matrix, a 4 × 6 matrix, or an 8 × 8 matrix without direct contact to at least one respective other optical waveguide.

In an embodiment, the component carrier further comprises an optical chip connected to the optical waveguide, wherein the cap structure and the optical waveguide are vertically shifted in a thickness direction of the stack from the optical chip. This may bring the advantage of reducing the spatial distance between the optical waveguide and the optical chip and thus enhance the transmission of the electromagnetic waves.

In an embodiment, the insulating cap structure is a solder resist so that the cap structure is arranged on the solder resist.

In an embodiment, the optical waveguide, and the cap structure are formed on both opposing main surfaces of the laminated stack so that the optical waveguide can be cladded at the top and bottom sides.

In an embodiment, in a cross-sectional view, the cap structure is substantially U-shaped. As a result, the optical waveguide can be cladded even at the lateral sides.

In an embodiment, the optical wave guide can be a glass fiber structure or a component. The cap structure can be adapted to any shape of the optical waveguide.

In an embodiment, an optional shielding structure can shield at least against one of electromagnetic radiation, in particular high-frequency radiation, heat radiation, infrared radiation, light, and humidity; and/or the shielding structure is configured to protect a signal integrity of a signal being transported within the optical waveguide.

In an embodiment, on top of the cap structure or on top of the shielding structure, at least one of a surface finish and a further solder resist is formed.

In an embodiment, the component carrier comprises at least one of the following features: the component carrier comprises at least one component being surface mounted on and/or embedded in the component carrier, wherein the at least one component is in particular selected from a group consisting of an electronic component, an electrically non-conductive and/or electrically conductive inlay, a heat transfer unit, a light guiding element, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier, and a logic chip; wherein at least one of the electrically conductive layer structures of the component carrier comprises at least one of the group consisting of copper, aluminum, nickel, silver, gold, palladium, and tungsten, any of the mentioned materials being optionally coated with supra-conductive material such as graphene; wherein the cap structure comprises at least one of the group consisting of copper, aluminum, nickel, silver, gold, palladium, and tungsten, any of the mentioned materials being optionally coated with supra-conductive material such as graphene; wherein the electrically insulating layer structure comprises at least one of the group consisting of resin, in particular reinforced or non-reinforced resin, for instance epoxy resin or bismaleimide-triazine resin, ABF, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide; wherein the electrically insulating cap structure comprises at least one of the group consisting of resin, in particular reinforced or non-reinforced resin, for instance epoxy resin or bismaleimide-triazine resin, ABF, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide, a resin, and a mold compound, wherein the component carrier is shaped as a plate; wherein the component carrier is configured as one of the group consisting of a printed circuit board, a substrate, and an interposer; wherein the component carrier is configured as a laminate-type component carrier.

In an embodiment of the method of manufacturing, the cap structure is formed by one of spin coating and spray coating.

In an embodiment of the method of manufacturing, the optical waveguide, the stack and/or the cap structure is formed by one of 3D-printing and nano-imprint lithography, wherein preferably the optical waveguide, the cap structure and/or at least one of the electrically insulating layer structures is made of a glass material or an optical organic polymer material. It is possible that the optical waveguide, the stack and the cap structure are made of the optical organic polymer material, which can preferably be manufactured in a common 3D-printing or nano-imprint lithography process. Advantageously, any desired shape of the optical waveguide can be achieved by a simple and fast manufacturing method.

In an embodiment of the method of manufacturing, the electrically insulating cap structure is a solder resist.

In an embodiment of the method of manufacturing, the optical waveguide and the cap structure are formed on both opposing main surfaces of the laminated stack. The component carrier can be symmetrically manufactured.

In an embodiment of the method of manufacturing, the cap structure is manufactured at least by one of plating and sputtering. Assembly or mounting machines are not necessary. The cap structure can be adapted to any shape of the optical waveguide. The cap structure can be arranged at any location of the component carrier and is not limited in terms of layout or geometrical complexity of the component carrier. The cap structure can have a variable thickness which is adapted to the desired cladding efficiency. The thickness and weight of the component carrier can be reduced as compared to a conventional component carrier having a shielding made of a prefabricated metal sheet.

In an embodiment of the method, the step of forming a cap structure selectively covering an optical waveguide at an exterior surface of the laminated stack comprises the following sub-steps: providing a solid glass body on or above the stack; and laser-processing the glass body to form a reflection layer inside the glass body, the reflection layer delimits the optical waveguide from the cap structure so that the optical waveguide and the cap structure are formed in the glass body. Advantageously, any desired shape of the optical waveguide can be achieved by a simple and fast manufacturing method.

In the context of the present disclosure, the term “exterior surface of the laminated stack” may particularly denote an outermost surface of the laminated stack and/or a main surface of the laminated stack. The main surface of the laminated stack can be defined by an outermost laminated layer of the laminated stack. One main surface of the laminated stack can be that surface where contact pads or terminals are arranged. The main surface of the component carrier can also be that surface which is perpendicularly orientated to a direction in which layers of the component carrier are superposed onto each other. However, the scope is not limited to these definitions.

In the context of the present disclosure, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, and an IC (integrated circuit) substrate. A component carrier may also be a hybrid board combining different ones of the above-mentioned types of component carriers.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane.

In an embodiment, the component carrier is shaped as a plate. This contributes to the compact design, wherein the component carrier nevertheless provides a large basis for mounting components thereon. Furthermore, in particular, a naked die as example for an embedded electronic component, can be conveniently embedded thanks to its small thickness into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming through-holes through the laminate, for instance by laser drilling or mechanical drilling, and by filling them with electrically conductive material (in particular copper), thereby forming vias as through-hole connections. Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier having substantially the same size as a component (in particular an electronic component) to be mounted thereon. More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) or a photo-imageable or dry-etchable organic material like epoxy-based build-up material (such as epoxy-based build-up film) or polymer compounds like polyimide, polybenzoxazole, or benzocyclobutene.

In an embodiment, the at least one electrically insulating layer structure comprises at least one of the group consisting of resin (such as reinforced or non-reinforced resins, for instance epoxy resin or bismaleimide-triazine resin), cyanate ester, polyphenylene derivate, glass (in particular glass fibers, multi-layer glass, glass-like materials), prepreg material (such as FR-4 or FR-5), polyimide, polyamide, liquid crystal polymer (LCP), epoxy-based build-up film, polytetrafluoroethylene (Teflon®), a ceramic, and a metal oxide. Teflon is a registered trademark of The Chemours Company FC LLC of Wilmington, Delaware, U.S.A. Reinforcing materials such as webs, fibers or spheres, for example made of glass (multilayer glass) may be used as well. Although prepreg particularly FR4 are usually preferred for rigid PCBs, other materials in particular epoxy-based build-up film or photo-imageable dielectric material for substrates may be used as well. For high frequency applications, high-frequency materials such as polytetrafluoroethylene, liquid crystal polymer and/or cyanate ester resins, low temperature cofired ceramics (LTCC) or other low, very low or ultra-low DK materials may be implemented in the component carrier as electrically insulating layer structure.

In an embodiment, the at least one electrically conductive layer structure comprises at least one of the group consisting of copper, aluminum, nickel, silver, gold, palladium, and tungsten. Although copper is usually preferred, other materials or coated versions thereof are possible as well, in particular, materials coated with a supra-conductive material such as graphene.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example another optical waveguide or a light conductor connection), an electronic component, or combinations thereof. For example, the component can be an active electronic component, a passive electronic component, an electronic chip, a storage device (for instance a DRAM or another data memory), a filter, an integrated circuit, a signal processing component, a power management component, an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferromagnetic element, for instance a ferrite core) or may be a paramagnetic element. However, the component may also be a substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component of the component carrier.

In an embodiment, the component carrier is a laminate-type component carrier. In such an embodiment, the component carrier is a compound of multiple layer structures which are stacked and connected together by applying a pressing force and/or heat.

The aspects defined above and further aspects of the disclosure are apparent from the examples of embodiment to be described hereinafter and are explained with reference to these examples of embodiment.

### BRIEF DESCRIPTION OF THE DRAWINGS

FIG. 1 illustrates a cross-sectional view of a component carrier according to an exemplary embodiment of the disclosure.

FIG. 2 illustrates a method of manufacturing a component carrier according to an exemplary embodiment of the disclosure.

FIG. 3 illustrates a cross-sectional view of a component carrier according to an exemplary embodiment of the disclosure.

FIG. 4 illustrates a cross-sectional view of a component carrier according to an exemplary embodiment of the disclosure.

FIG. 5 illustrates a cross-sectional view of a component carrier according to an exemplary embodiment of the disclosure.

FIG. 6 illustrates a cross-sectional view of a component carrier according to an exemplary embodiment of the disclosure.

FIG. 7 illustrates a cross-sectional view of a component carrier according to an exemplary embodiment of the disclosure.

### DETAILED DESCRIPTION OF ILLUSTRATED EMBODIMENTS

The illustrations in the drawings are schematically presented. In different drawings, similar or identical elements are provided with the same reference signs.

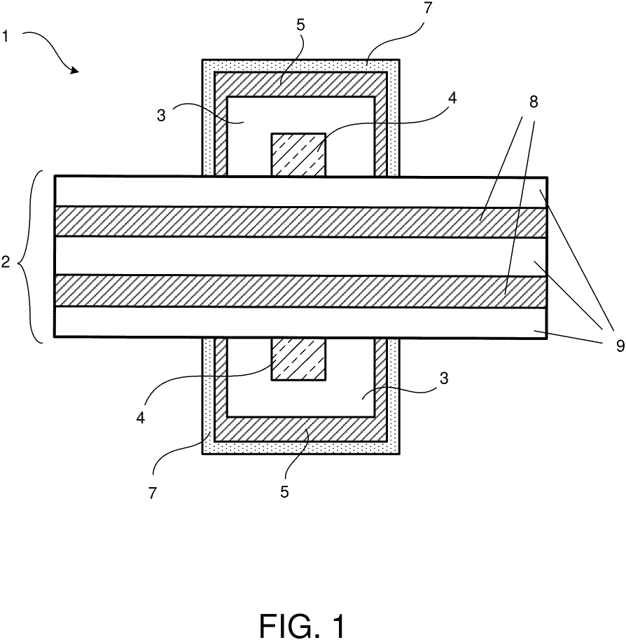

FIG. 1 illustrates a cross-sectional view of a component carrier 1 according to an exemplary embodiment of the disclosure. The component carrier 1 is shaped as a plate. The component carrier 1 can be configured as one of the group consisting of a printed circuit board, a substrate, and an interposer. The component carrier 1 can be configured as a laminate-type component carrier.

The component carrier 1 comprises a laminated stack 2 having a plurality of electrically conductive layer structures 8 and a plurality of electrically insulating layer structures 9.

At least one of the electrically conductive layer structures 8 of the component carrier can comprise at least one material of the group consisting of copper, aluminum, nickel, silver, gold, palladium, and tungsten, any of the mentioned materials being optionally coated with supra-conductive material such as graphene.

At least one of the electrically insulating layer structures 9 can comprise at least one of the group consisting of resin, in particular reinforced or non-reinforced resin, for instance epoxy resin or bismaleimide-triazine resin, ABF, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide.

The component carrier 1 comprises an electrically insulating cap structure 3 selectively covering an optical waveguide 4 at an exterior surface of the laminated stack 2.

The optical waveguide 4 can be a waveguide core cladded by the cap structure 3 which is an electrically insulating cap structure 3. The cap structure 3 and at least one of the electrically insulating layer structures 9 can be made of the same material. At least one of the cap structure 3, the optical waveguide 4, and the electrically insulating layer structures 9 is made of an optical polymeric material and/or glass material.

The stack 2 can be a printed circuit board, wherein the optical waveguide 4 can be fully embedded in the cap structure 3. The cap structure 3 can comprises a layer thickness being 3 times larger than a layer thickness of the optical waveguide 4. The optical waveguide 4 can comprise a cross-section having an edged shape or a round shape.

In the present embodiment, the electrically insulating cap structure 3 can be a solder resist. In another embodiment, the electrically insulating cap structure 3 can comprise at least one of the group consisting of resin, in particular reinforced or non-reinforced resin, for instance epoxy resin or bismaleimide-triazine resin, ABF, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide, a resin, and a mold compound. Alternatively, cap structure 3 is made of an electrically conductive material, such as a metal. Preferably, the metal can be copper or aluminum.

The component carrier 1 can optionally comprise a shielding structure 5 on the cap structure 3 for shielding the optical waveguide 4. The shielding structure 5 can be arranged above the cap structure 3. The shielding structure 5 can comprise at least one of the group consisting of copper, aluminum, nickel, silver, gold, palladium, and tungsten, any of the mentioned materials being optionally coated with supra-conductive material such as graphene. The shielding structure 5 can also exclusively comprise graphene.

The shielding structure 5 can shield at least against one of electromagnetic radiation, in particular high-frequency radiation, heat radiation, infrared radiation, light, and humidity. The shielding structure 5 can be configured to protect a signal integrity of a signal being transported within the optical waveguide 4.

In an embodiment, the cap structure 3 or the shielding structure 5 does not carry a signal which is used for a signal processing or a current which is used for a power supply. The cap structure 3 or the shielding structure 5 is not necessarily connected to a port or pad for signal processing or power supply. In an embodiment, the cap structure 3 or the shielding structure 5 does exclusively have a shielding functionality.

In the present embodiment, the optical waveguide 4, the cap structure 3 and optionally the shielding structure 5 are formed only on one of both opposing main surfaces of the laminated stack 2. However, in an alternative embodiment, the optical waveguide 4, the cap structure 3 and optionally the shielding structure 5 can be formed on both opposing main surfaces of the laminated stack 2. The shielding structure 5 on both opposing main surfaces of the laminated stack 2 can shield one and the same optical waveguide 4.

In the present embodiment, the cap structure 3 and optionally the shielding structure 5 are substantially U-shaped in the cross-sectional view of FIG. 1.

In an embodiment, the optical waveguide 4 can completely be surrounded by the stack 2 and the cap structure 3 in the cross section of FIG. 1. The optical waveguide 4 can also completely be surrounded by the stack 2, the cap structure 3 and optionally the shielding structure 5 in the cross section of FIG. 1. The shielding structure 5 can selectively or globally be applied on the cap structure 3, and optionally on the exterior surface of the laminated stack 2.

The optical waveguide 4 can be a glass fiber structure or a component.

Such a component can be surface mounted on and/or embedded in the component carrier 1, wherein the component is in particular selected from a group consisting of an electronic component, an electrically nonconductive and/or electrically conductive inlay, a heat transfer unit, a light guiding element, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier 1, and a logic chip. The component can be surface-mounted on the exterior surface of the laminated stack 2, or the component can be embedded in a cavity in the laminated stack 2, where the cavity forms a part of the exterior surface of the laminated stack 2.

In a modified embodiment, at least one of a surface finish and a further solder resist can be formed on top of the cap structure 3 and/or the stack 2. For example, after processing interior layer structures of the component carrier 1, the stack 2 and/or the cap structure 3, it is possible to cover (in particular by lamination) one or both opposing main surfaces of the processed layer structures symmetrically or asymmetrically with one or more further electrically insulating layer structures 9 and/or electrically conductive layer structures 8. In other words, a build-up may be continued until a desired number of layers is obtained.

After having completed formation of the stack 2 of electrically insulating layer structures 9 and electrically conductive layer structures 8, it is possible to proceed with a surface treatment of the obtained layers structures or component carrier 1.

In particular, as the further solder resist, an electrically insulating solder resist may be applied to one or both opposing main surfaces of the layer stack 2 or component carrier 1 in terms of surface treatment. For instance, it is possible to form such as the further solder resist on an entire main surface and to subsequently pattern the layer of the further solder resist so as to expose one or more electrically conductive surface portions which shall be used for electrically coupling the component carrier 1 to an electronic periphery. The surface portions of the component carrier 1 remaining covered with the further solder resist may be efficiently protected against oxidation or corrosion, in particular surface portions containing copper.

It is also possible to apply a surface finish selectively to exposed electrically conductive surface portions of the stack 2 or the component carrier 1 in terms of surface treatment. Such a surface finish may be an electrically conductive cover material on exposed electrically conductive layer structures 8 (such as pads, conductive tracks, etc., in particular comprising or consisting of copper) on a surface of the component carrier 1 or the stack 2. If such exposed electrically conductive layer structures 8 are left unprotected, then the exposed electrically conductive component carrier material (in particular copper) might oxidize, making the component carrier less reliable. A surface finish may then be formed for instance as an interface between a surface mounted component and the component carrier 1. The surface finish has the function to protect the exposed electrically conductive layer structures 8 (in particular copper circuitry) and enable a joining process with one or more components, for instance by soldering. Examples of appropriate materials for a surface finish are OSP (Organic Solderability Preservative), Electroless Nickel Immersion Gold (ENIG), gold (in particular Hard Gold), chemical tin, nickel-gold, nickel-palladium, etc.

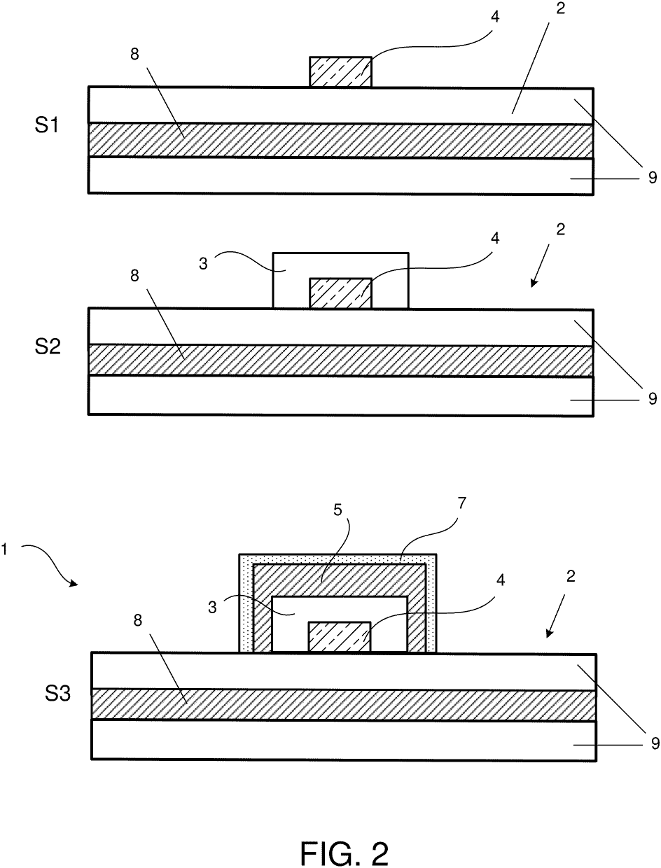

FIG. 2 illustrates a method of manufacturing a component carrier 1 according to an exemplary embodiment of the disclosure.

In a step S1, a laminated stack 2 having a plurality of electrically conductive layer structures 8 and a plurality of electrically insulating layer structures 9 is provided. In detail, the plurality of electrically insulating layer structures 9 comprises an optical waveguide 4 which is formed at an exterior surface of the laminated stack 2. The optical waveguide 4 can be a glass fiber structure or a component.

Such a component can be surface mounted on and/or embedded in the component carrier 1, wherein the component is in particular selected from a group consisting of an electronic component, an electrically nonconductive and/or electrically conductive inlay, a heat transfer unit, a light guiding element, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier 1, and a logic chip. The component can be surface-mounted on the exterior surface of the laminated stack 2, or the component can be embedded in a cavity in the laminated stack 2, where the cavity forms a part of the exterior surface of the laminated stack 2.

At least one of the electrically conductive layer structures 8 of the stack 2 can comprise at least one of the group consisting of copper, aluminum, nickel, silver, gold, palladium, and tungsten, any of the mentioned materials being optionally coated with supra-conductive material such as graphene.

At least one of the electrically insulating layer structures 9 of the stack 2 can comprise at least one of the group consisting of resin, in particular reinforced or non-reinforced resin, for instance epoxy resin or bismaleimide-triazine resin, ABF, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide.

In a step S2, an electrically insulating cap structure 3 is formed to selectively cover the optical waveguide 4. In the present embodiment, the electrically insulating cap structure 3 is a solder resist.

In another embodiment, the electrically insulating cap structure 3 can comprise at least one of the group consisting of resin, in particular reinforced or non-reinforced resin, for instance epoxy resin or bismaleimide-triazine resin, ABF, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide, a resin, and a mold compound.

A material of the electrically insulating cap structure 3, for example the solder resist, is applied as a paste, a dry film, a lamination film or a liquid onto the optical waveguide 4. The material of the electrically insulating cap structure 3 can be photoimageable and globally applied onto the optical waveguide 4 and optionally on the stack 2. Thereafter, the material of the electrically insulating cap structure 3 is selectively cured and exposed, for example by means of heat or UV light, and the remaining unexposed material of the electrically insulating cap structure 3 can be removed, for example by stripping.

Alternatively, the material of the electrically insulating cap structure 3 can be applied by screen printing, spraying or curtain coating, or it can selectively be applied by ink jet printing.

In a step S3, an optional shielding structure 5 is formed on the cap structure 3 for shielding the optical waveguide 4. The shielding structure 5 can be manufactured at least by one of plating, sputtering and three-dimensional printing. When plating, a thin seed layer can chemically be applied on the cap structure 3, which is followed by a galvanic plating step on the thus formed seed layer.

At least one of the shielding structure 5 and the cap structure 3 can be formed by one of spin coating and spray coating. At least one of the optical waveguide 4, the stack 2, the shielding structure 5 and the cap structure 3 can be formed by one of 3D-printing and nano-imprint lithography, wherein preferably at least one of the optical waveguide 4, the cap structure 3 and at least one of the electrically insulating layer structures 9 is made of a glass material or an optical organic polymer material. If the optical waveguide 4, the cap structure 3 and at least one of the electrically insulating layer structures 9 is made of a glass material, they can also be processed by laser processing.

The cap structure 3 can also be formed by subtractive or additive processes. As additive processes, SAP (Semi-additive processes) or mSAP (modified Semi-additive processes) can be utilized.

The cap structure 3 can selectively or globally applied on the exterior surface of the laminated stack 2.

In an embodiment, the cap structure 3 does not carry a signal which is used for a signal processing or a current which is used for a power supply. The cap structure 3 is not necessarily connected to a port or pad for signal processing or power supply. In an embodiment, the cap structure 3 does exclusively have a cladding or shielding functionality.

In the present embodiment, the optical waveguide 4, the cap structure 3 and the optional shielding structure 5 are formed on only one of the opposing main surfaces of the laminated stack 2. In an alternative embodiment, the cap structure 3 and optionally the shielding structure 5 can be formed on both opposing main surfaces of the laminated stack 2. The cap structure 3 on both opposing main surfaces of the laminated stack 2 can clad one and the same optical waveguide 4. The component carrier 1 can symmetrically be formed, that is, the optical waveguides 4, the cap structures 3 and optionally the shielding structures 5 are arranged on both opposing main surfaces of the laminated stack 2.

In an embodiment, the component carrier 1 can perform a high frequency application, in particular 5G. The optical waveguide 4 can be shielded at least against one of electromagnetic radiation, in particular highfrequency radiation, heat radiation, infrared radiation, light, and humidity. In general, the cap structure 3 can be configured to protect a signal integrity of a signal being transported within the optical waveguide 4.

In the present embodiment, the cap structure 3 and optionally the shielding structure 5 can be formed to be substantially U-shaped in the cross-sectional view of FIG. 2 so that the optical waveguide 4 is shielded even at the lateral sides.

In an embodiment, the optical waveguide 4 can completely be surrounded by the stack 2 and the cap structure 3 in the cross section of FIG. 2. The optical waveguide 4 can also completely be surrounded by the stack 2, the cap structure 3 and optionally the shielding structure 5 in the cross section of FIG. 2.

In a modified embodiment, at least one of a surface finish or further solder resist 7 can be formed on top of the cap structure 3 and/or the stack 2. For example, after processing interior layer structures of the component carrier 1, the stack 2 and/or the cap structure 3, it is possible to cover (in particular by lamination) one or both opposing main surfaces of the processed layer structures symmetrically or asymmetrically with one or more further electrically insulating layer structures 9 and/or electrically conductive layer structures 8. In other words, a build-up may be continued until a desired number of layers is obtained.

After having completed formation of the stack 2 of electrically insulating layer structures 9 and electrically conductive layer structures 8, it is possible to proceed with a surface treatment of the obtained layers structures or component carrier 1.

In particular, as the further solder resist, an electrically insulating further solder resist 7 may be applied to one or both opposing main surfaces of the layer stack 2 or component carrier 1 in terms of surface treatment. For instance, it is possible to form such as the further solder resist 7 on an entire main surface and to subsequently pattern the layer of the further solder resist 7 so as to expose one or more electrically conductive surface portions which shall be used for electrically coupling the component carrier 1 to an electronic periphery. The surface portions of the component carrier 1 remaining covered with the further solder resist 7 may be efficiently protected against oxidation or corrosion, in particular surface portions containing copper.

It is also possible to apply a surface finish 7 selectively to exposed electrically conductive surface portions of the stack 2 or the component carrier 1 in terms of surface treatment. Such a surface finish 7 may be an electrically conductive cover material on exposed electrically conductive layer structures 8 (such as pads, conductive tracks, etc., in particular comprising or consisting of copper) on a surface of the component carrier 1 or the stack 2. If such exposed electrically conductive layer structures 8 are left unprotected, then the exposed electrically conductive component carrier material (in particular copper) might oxidize, making the component carrier less reliable. The surface finish 7 may then be formed for instance as an interface between a surface mounted component and the component carrier 1. The surface finish 7 has the function to protect the exposed electrically conductive layer structures 8 (in particular copper circuitry) and enable a joining process with one or more components, for instance by soldering. Examples of appropriate materials for a surface finish are OSP (Organic Solderability Preservative), Electroless Nickel Immersion Gold (ENIG), gold (in particular Hard Gold), chemical tin, nickel-gold, nickel-palladium, etc.

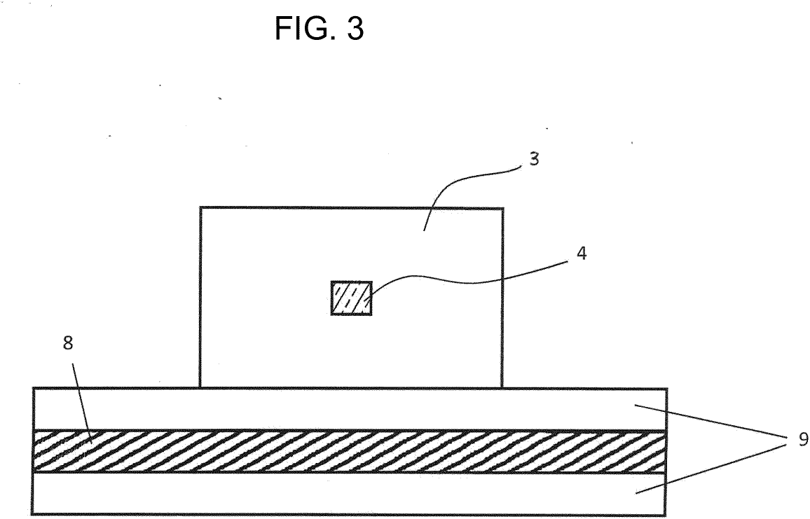

FIG. 3 illustrates a cross-sectional view of a component carrier according to an exemplary embodiment of the disclosure. The cap structure 3 comprises a layer thickness being at least 3 times larger than a layer thickness of the optical waveguide 4. This relationship allows less signal losses through the optical waveguide 4 so that a high-quality signal transmission can be ensured. In the embodiment of FIG. 3, the optical waveguide 4 is centrally arranged within the cap structure 3 so that the cap structure 3, which acts as a cladding, fully surrounds the optical waveguide 4 in a cross-section of the component carrier. Preferably, the optical waveguide 4 is substantially arranged at a center of the cap structure 3, thereby ensuring the optimum signal loss reduction. As a matter of course, the optical waveguide 4 can still be arranged at the bottom of the cap structure 3 as shown in FIG. 1, where the optical waveguide 4 is in direct contact with the uppermost electrically insulating layer structure 9 of the stack. This uppermost electrically insulating layer structure 9 of the stack also ensures sufficient optical wave reflection inside the optical waveguide 4 so that signal losses are still minimized.

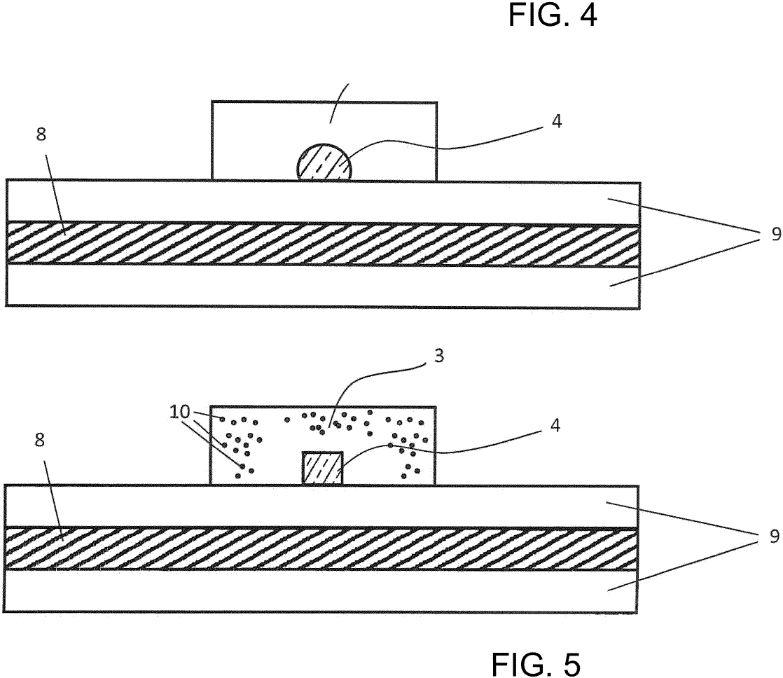

FIG. 4 illustrates a cross-sectional view of a component carrier according to an exemplary embodiment of the disclosure. The optical waveguide 4 comprises a cross-section having a round shape, while the optical waveguide 4 in FIG. 1 comprises a cross-section having an edged shape. These shapes may bring the advantage of high freedom of the component carrier design. In example, the edged shape may comprise triangular, rectangular, or hexagonal shapes. The round shape can comprise circular or elliptical shapes.

FIG. 5 illustrates a cross-sectional view of a component carrier according to an exemplary embodiment of the disclosure. The cap structure 3 comprises a filling material 10 in a distance of at least 20 µm from the optical waveguide 4. Alternatively or in addition, the filling material 10 can be provided in the uppermost electrically insulating layer structure 9 of the stack. The filling material 10 can be constituted by solid particles or by open and/or closed pores filled by a fluid, preferably gas filled pores. That is, the cap structure 3 can comprise a porous material having the open and/or closed pores 10 being filled by a fluid, preferably gas filled pores. This may bring the advantage of reducing the weight of the component carrier, while still ensuring reliable transmission of the electromagnetic waves. In an example, the porous material may comprise air, nitrogen, carbon dioxide, or argon. In another example, the porous material may comprise ethylene glycol, glycerin, or water.

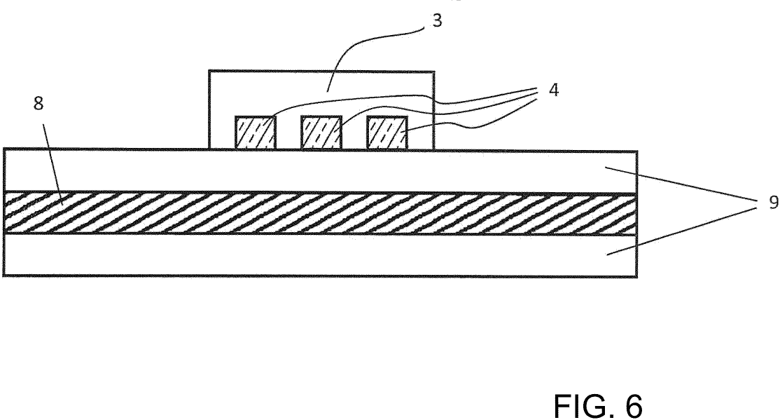

FIG. 6 illustrates a cross-sectional view of a component carrier according to an exemplary embodiment of the disclosure. A plurality of the optical waveguides 4, preferably up to 64 optical waveguides, are arranged side by side without direct contact to each other. This may bring the advantage of increasing the transmission of electromagnetic waves in the component carrier. In an example, the plurality of optical waveguides may be arranged randomly without direct contact to at least one respective other optical waveguide 4. In a preferred other example, the plurality of optical waveguides 4 may be arranged in a structured matrix in a cross-section of the component carrier, for example a 1 × 8 matrix (1 column by 8 rows), a 3 × 4 matrix (3 columns by 4 rows), a 4 × 6 matrix (4 columns by 6 rows), or an 8 × 8 matrix (8 columns by 8 rows) without direct contact to at least one respective other optical waveguide 4.

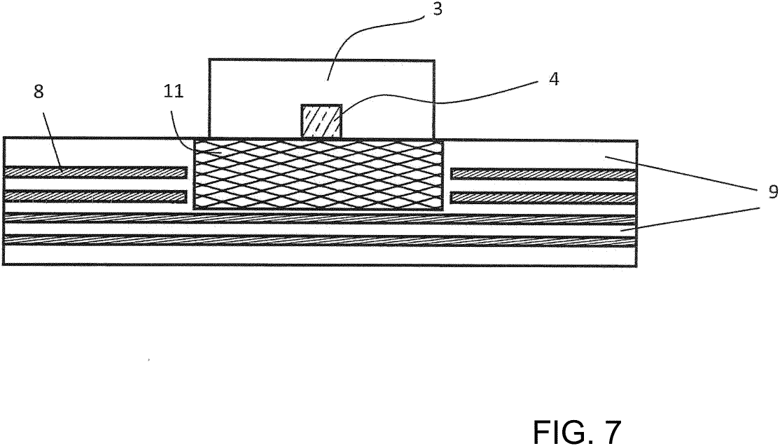

FIG. 7 illustrates a cross-sectional view of a component carrier according to an exemplary embodiment of the disclosure. The component carrier further comprises an optical chip 11 connected to the optical waveguide 4, wherein the cap structure 3 and the optical waveguide 4 are vertically shifted in a thickness direction of the stack from the optical chip 11. Preferably, optical chip 11 is arranged at the uppermost electrically insulating layer structure 9 of the stack. This may bring the advantage of reducing the spatial distance between the optical waveguide 4 and the optical chip 11 and thus enhance the transmission of the electromagnetic waves.

All embodiments of the component carrier can be provided in any size and in a compact size, in particular if the cap structure 3 is manufactured by plating, sputtering, a (photo)lithography process and/or three-dimensional printing. The cap structure 3 may comprise inorganic material, for example a metal, in particular copper or aluminum, or glass. Additionally and or alternatively, the cap structure 3 may comprise an organic material, in particular organic polymer material, for example epoxy resin. Furthermore, the cap structure 3 may comprise or consist of material layers arranged one layer on top of another layer. In one example, a layer comprising organic material and a further layer comprising the same or a different organic material may be located next to the other respective layer, while having direct contact. In another example, a layer comprising inorganic material and a further layer comprising organic material may be located next to the other respective layer, while having direct contact.

The cap structure 3 can also be applied on the optical waveguide 4 by lamination.

If the optical waveguide 4 as shown in FIGS. 1 to 7 is made of a glass material, it can be processed by laser processing. For instance, both the optical waveguide 4 and the cap structure 3 can be formed by a solid glass body. A laser can form a reflection layer with a desired depth (for example about 100 µm) inside the glass body, which reflection layer forms a border between the optical waveguide 4 and the cap structure 3. A thus manufactured glass body comprises the optical waveguide 4 as an optical core and glass material surrounding the optical core/optical waveguide 4 forming the cladding/cap structure 3.

It should be noted that the term “comprising” does not exclude other elements or steps and the article “a” or “an” does not exclude a plurality. Also, elements described in association with different embodiments may be combined.

Implementation of the teachings of the disclosure is not limited to the preferred embodiments shown in the figures and described above. Instead, a multiplicity of variants is possible which variants use the solutions shown and the principle according to the disclosure even in the case of fundamentally different embodiments.

1. A component carrier, comprising:
a laminated stack comprising a plurality of electrically conductive layer structures and a plurality of electrically insulating layer structures; and
an electrically insulating cap structure selectively covering an optical waveguide at an exterior surface of the laminated stack.

2. The component carrier according to claim 1, wherein the optical waveguide is a waveguide core cladded by the electrically insulating cap structure.

3. The component carrier according to claim 1, wherein the electrically insulating cap structure and at least one of the electrically insulating layer structures are made of the same material.

4. The component carrier according to claim 1, wherein at least one of the electrically insulating cap structure, the optical waveguide, and at least one of the electrically insulating layer structures is made of an optical polymeric material and/or glass material.

5. The component carrier according to claim 1, wherein the stack is a printed circuit board, wherein the optical waveguide is fully embedded in the electrically insulating cap structure.

6. The component carrier according to claim 1, wherein the electrically insulating cap structure comprises a layer thickness being at least 3 times larger than a layer thickness of the optical waveguide.

7. The component carrier according to claim 1, wherein the optical waveguide comprises a cross-section having an edged shape or a round shape.

8. The component carrier according to claim 1, wherein at least one of the electrically insulating cap structure and at least one of the electrically insulating layer structures comprise a filling material preferably located a distance of at least 20 µm from the optical waveguide.

9. The component carrier according to claim 1, wherein the electrically insulating cap structure comprises a porous material having open and/or closed pores being filled by a fluid, preferably gas filled pores.

10. The component carrier according to claim 1, wherein a plurality of the optical waveguides, preferably up to 64 optical waveguides, are arranged side by side without direct contact with each other.

11. The component carrier according to claim 1, further comprising:
an optical chip connected to the optical waveguide, wherein the electrically insulating cap structure and the optical waveguide are vertically shifted in a thickness direction of the stack from the optical chip.

12. The component carrier according to claim 1, wherein the electrically insulating cap structure is a solder resist.

13. The component carrier according to claim 1, wherein the optical waveguide and the electrically insulating cap structure are formed on both opposing main surfaces of the laminated stack.

14. The component carrier according to claim 1, wherein in a cross-sectional view, the electrically insulating cap structure is substantially U-shaped.

15. The component carrier according to claim 1, wherein the optical waveguide is a component.

16. The component carrier according to claim 1, wherein on top of the electrically insulating cap structure, at least one of a surface finish and a further solder resist is formed.

17. The component carrier according to claim 1, further comprising at least one of the following features:
the component carrier comprises at least one component being surface mounted on and/or embedded in the component carrier, wherein the at least one component is in particular selected from a group consisting of an electronic component, an electrically non-conductive and/or electrically conductive inlay, a heat transfer unit, a light guiding element, an energy harvesting unit, an active electronic component, a passive electronic component, an electronic chip, a storage device, a filter, an integrated circuit, a signal processing component, a power management component, an optoelectronic interface element, a voltage converter, a cryptographic component, a transmitter and/or receiver, an electromechanical transducer, an actuator, a microelectromechanical system, a microprocessor, a capacitor, a resistor, an inductance, an accumulator, a switch, a camera, an antenna, a magnetic element, a further component carrier, and a logic chip;
wherein at least one of the electrically conductive layer structures of the component carrier comprises at least one of the group consisting of copper, aluminum, nickel, silver, gold, palladium, and tungsten, any of the mentioned materials being optionally coated with supra-conductive material such as graphene;
wherein the electrically insulating layer structures comprise at least one of the group consisting of resin, in particular reinforced or non-reinforced resin, for instance epoxy resin or bismaleimide-triazine resin, ABF, FR-4, FR-5, cyanate ester, polyphenylene derivate, glass, prepreg material, polyimide, polyamide, liquid crystal polymer, epoxy-based build-up film, polytetrafluoroethylene, a ceramic, and a metal oxide;
wherein the electrically insulating cap structure comprises at least one of the group consisting of resin, in particular reinforced or non-reinforced resin, for instance epoxy resin or bismaleimide-triazine resin, ABF, FR-4, FR-5, cyanate ester, polyphenylene derivate, glass, prepreg material, polyimide, polyamide, liquid crystal polymer, epoxy-based build-up film, polytetrafluoroethylene, a ceramic, a resin, and a mold compound;
wherein the component carrier is shaped as a plate;
wherein the component carrier is configured as one of the group consisting of a printed circuit board, a substrate, and an interposer;
wherein the component carrier is configured as a laminate-type component carrier.

18. The component carrier according to claim 1, further comprising:
a shielding structure on the electrically insulating cap structure for shielding the optical waveguide, wherein the shielding structure shields at least against one of electromagnetic radiation, in particular high-frequency radiation, heat radiation, infrared radiation, light, and humidity; and/or the shielding structure is configured to protect a signal integrity of a signal being transported within the optical waveguide.

19. A method of manufacturing a component carrier, the method comprising:
providing a laminated stack having a plurality of electrically conductive layer structures and a plurality of electrically insulating layer structures; and
forming a cap structure selectively covering an optical waveguide at an exterior surface of the laminated stack.

20. The method according to claim 19, wherein the cap structure is formed by one of spin coating and spray coating.

21. The method according to claim 19, wherein at least one of the optical waveguide, the stack, and the cap structure is formed by one of 3D-printing and nano-imprint lithography, wherein preferably at least one of the optical waveguide, the cap structure and at least one of the plurality of electrically insulating layer structures is made of an optical organic polymer material or a glass material.

22. The method according to claim 19, wherein the cap structure is manufactured at least by one of plating and sputtering.

23. The method according to claim 19, further comprising:
forming a shielding structure on the cap structure for shielding the optical waveguide.

24. The method according to claim 19, wherein
the step of forming a cap structure selectively covering an optical waveguide at an exterior surface of the laminated stack comprises the following sub-steps:
providing a solid glass body on or above the stack; and
laser-processing the glass body to form a reflection layer inside the glass body, the reflection layer delimiting the optical waveguide from the cap structure so that the optical waveguide and the cap structure are formed in the glass body.
